(19) United States
(12) Patent Application Publication
(10) Pub. No.: US 2004/0187916 A1
(43) Pub. Date: Sep. 30, 2004

(54) Solar cell and method for production thereof

(76) Inventor: Rudolf Hezel, Hameln (DE)

Correspondence Address: DENNISON, SCHULTZ, DOUGHERTY & MACDONALD, 1727 KING STREET, SUITE 105, ALEXANDRIA, VA, 22314, US

(21) Appl. No.: 10/486,821

(22) PCT Filed: Aug. 28, 2002
(86) PCT No.: PCT/EP02/09578

(30) Foreign Application Priority Data
Aug. 31, 2001 (DE) 101 42 481.7

(51) Int. Cl. H01L 31/00

(52) U.S. Cl. 136/256; 438/98

(57) ABSTRACT

The invention relates to a method for production of a solar cell (10) and said cell. According to the invention, a high efficiency may be achieved, whereby, on the rear side of the solar cell, first and second contacts (26, 28) are arranged on projections (18), or the flanks thereof (20, 22), for collecting minority and majority charge carriers.

The invention relates to a solar cell including a semiconductor substrate with first and second contacts for collecting and discharging minority and majority charge carriers generated by incident radiation energy in the semiconductor substrate, whereby the back surface has at least regionally parallel-running linear and bar-like elevations with respectively first and second longitudinal flanks restricting first trenches, whereby the first and second contacts are arranged spaced from one another on the back surface of the semiconductor substrate. Furthermore, the invention makes reference to a method for manufacturing a solar cell, including a semiconductor substrate with front and back in which minority and majority charge carriers are generated by incident radiation, which are collected and discharged through first and second contacts running over elevations of the back surface of the semiconductor substrate having elevations restricting first trenches having strip-like and bar-like first and second longitudinal flanks, whereby the first and second electrical contacts are directly installed on the back surface or are applied on regions of the semiconductor substrate of the first and second electrical contacts following total area or largely total area covering of the back area with a passivation layer, and if need be removal of regions of the passivation layer.

The overwhelming majority of solar cells used at this time usually consists of a semiconductor element of one conduction type (for example, p-type conducting), in which an area of the opposite conduction type (for example, n-type conducting) is generated, and electrical contacts are applied on both sides of the semiconductor body. The electron-hole pair (minority-majority charge carrier) generated by the incident light is separated in the electric field of the p-n transition. The electrons migrate to the n-area, the holes to the p-area, where they respectively drain through metal contacts. These metal contacts are constructed latticed on the front side to make light incidence possible.

Attaching the front side contact on the back as well, and consequently to gather both charge carrier types on the side facing away from the light in order to eliminate light shading largely through these strip-like constructed metal fingers, and to configure the connection of the solar cells more economically is known (U.S. Pat. No. 4,315,097). Due to the extremely complex technology, these so-called IBC (Interdigitated Back Contact) solar cells are chiefly used for highly concentrated light, thus for very high current densities (M. D. Lammert, R. J. Schwartz, “The Interdigitated Back Contact Solar Cell. A Silicon Solar Cell for Use in Concentrated Sunlight,” IEEE Transactions on Electron Devices, vo. ED-24, No. 4, p. 337-343 (1977)).

The point contact (PC) solar cell is very similar to the IBC cell (R. M. Swanson, Solar Cells, vol. 17, No. 1, p. 85-118 (1986)).

Another solar cell with both contacts on one side of the semiconductor body is described in DE 41 43 083 A1 (=EP 0 548 863 B1).

A solar cell with discrete voltage-generating regions is to be gathered known on the basis of U.S. Pat. No. 4,376,872, which are constructed in a monocrystal. The cells have doped regions of different light conductivity which are separated by V-shaped trenches whose flanks are bombarded with ions to obtain the desired conductivity. For this purpose, the monocrystal substrate is set up on a source of ions such that only the flank to be doped is exposed to the ion stream. After doping the flanks, a metal layer is applied to the flanks of the trenches to cover the flanks completely. The individual units are connected in series.

A tandem solar cell can be inferred from U.S. Pat. No. 4,295,002 which has solar cell regions of Si connected trapezoidally in series on both sides the flanks of which consist of ⁺-GaP-or p⁺-GaP layers. On the exterior, the opposite-lying n⁺-GaP and p⁺-GaP layers are completely covered with a metal layer with the exception of a narrow crest region. Furthermore, an SiO₂ extends along the crest of the solar cell region which-is externally covered with a metal layer.

The present invention is based upon the problem of perfecting a solar cell as well as a method of the type mentioned at the beginning such that a structure of the solar cell which is easy to manufacture is possible while at the same time attaining a high degree of efficiency. In particular, it should be possible for a simple almost self-adjusting arranging of the first and second contacts collecting the majority and the minority charge carriers to take place. Moreover the contacts should not lead to a shadowing that worsens the degree of efficiency of the solar cell.

The problem is basically solved in accordance with the invention through a solar cell of the type mentioned at the beginning in that the first and second longitudinal flank of the elevation change over into each other through an exterior segment running parallel or approximately parallel to the plane prestressed from the semiconductor substrate, in that successive elevations delimit a trench with trench bottom, in that at least some of the contacts extend on the first longitudinal flank of the elevations and the second contacts extend on the second longitudinal flanks of the elevations, and in that the first and second contacts are spaced from one another on the trench side as well as on the exterior segment.

The theory of the invention is realized by a system of contacts arranged on the flanks of the back running elevations which can be designated as emitter contacts for collecting minority conduction carriers and as base contacts for collecting majority charge carriers. The actualization of the arrangement of contacts on the longitudinal flanks of the linear elevations extending on the back surface of the semiconductor substrate is moreover not restricted to a certain solar cell type. A realization can rather be based upon p-n transitions generated by doping and heterostructures as well as upon the induction of an electric field by a metal or by surface insulator charges. The semiconductor material of the solar cell, n-type or p-type conducting, can be monocrystalline, polycrystalline or amorphous or an element of a connection semiconductor. A doping with gallium, indium or aluminum should also be used in the event of crystalline silicon in addition or a boron or phosphorus doping. The use of thin layer semiconductors such as copper-indium-selenide or sulfide, cadmium telluride or gallium arsenide is likewise possible.

The light incident through a double contact lattice structure (bifacial solar cell) can also be used and finally a simple solar cell illuminable on both sides or a solar cell collecting minority charge carriers on both sides can be made available. The latter serves for the best possible utilization of ambient scattered light as well as for effective collection of light-generated charge carriers, especially when a cheaper semiconductor substrate with reduced diffusion length of the minority charge carrier is present. In special cases, the double contact lattice structure can also be mounted on the front side facing the direct sunlight instead of on the back. This is especially advantageous for thin layer solar cells in which the thin semiconductor layer is situated on a foreign substrate, and the mostly difficult insertion of the back contact between the semiconductor and the foreign substrate is avoided through the arrangement of the invention (S. Roberts et al., Proc. 2^{nd} WCPEC (1998), p. 1449).

It is provided in accordance with the invention that the first contact is arranged regionally on the one first longitudinal flank and the second contact is regionally arranged on the opposite second flank of the same elevation of the semiconductor substrate surface, whereby the respective contact or its metallization can extent even to a small extent over the angular or rounded off edges of the plateau-like region of the elevations provided, which pass over into the longitudinal flanks. Of course a sufficient distance between the first and second contact must be guaranteed in adjoining regions to avoid short circuits.

The elevations delimit trenches which respectively have a trench bottom which runs parallel to the plane spanned by the semiconductor substrate. The region is not covered by an electrical contact so that light can enter. Short circuits between contacts are likewise ruled out.

In particular, it is provided that the elevations can have a U, V or sawtooth shape in section. The first or second contact advantageously extends up to the outer longitudinal rim of the first or the second longitudinal flank of the elevation.

A basic advantage of the solar cell of the invention which can be designated as a Back-OECO (Obliquely Evaporated Contact) or Rear OECO solar cell exists due to the fact that, owing to the elevations, the contacts can be applied and defined completely free of masks and adjustment by oblique evaporation deposition in a vacuum. In particular, the reciprocal separation of the two contact fingers to avoid short circuits can be guaranteed automatically through the upper side of the elevations to be configured metallization-free simply on the basis of oblique evaporation deposition and must not, as with the known described back side collecting solar cells (IBC or point contact cells) be attained by photolithographic methods which are extremely difficult to implement on larger surfaces and expensive. The spacing of the two contacts or their metallization among one another can be adjusted simply through the width of the elevations and therewith their thickness. The principle of self-shadowing is used with oblique evaporation deposition of the materials for the contacts in a vacuum. High disc throughput, very good metal use and simple handling are the basic advantages of this method in comparison with conventional vacuum evaporation deposition (Hezel, R., Proc. 13^{th} European PVSEC, Nice 1995, p. 115).

A further advantage of the theory of the invention consists in that, by construction of the elevation by insertion of trenches on the substrate back side with their depth, the remaining semiconductor substrate thickness can be established at the same time.

For the efficient collection of charge carriers on the backside, this must be designed differently according to material quality, that is diffusion length of the minority charge carriers. The support function of the elevations permits making the semiconductor thickness very thin without risk of breakage, which is especially significant for cheap material with low charge carrier lifetime.

The significance of the invention lies in the arrangement of the metal contacts, their exact separation from one another, and in the lining up of the solar cell units. The respective unit with preferably vertical flanks and preferably metal regions in the upper part on both sides of the elevations separated by wide, non-metallized trenches that are actively used for collecting charge carriers, since they are preferably provided with a diffused n⁺-type or inversion layer. The trenches which also can only be covered with a passivation layer possess wholly or partially a bottom surface which runs parallel to the plane spanned by the semiconductor substrate. The depth of the trenches largely determines the function of the backside collecting solar cells, since the minority carriers must diffuse through the base of the backside. This depth and therewith largely the thickness of the base can take place in accordance with the invention through the structuring of the backside and therewith be exactly adjusted to the diffusion length of the respective semiconductor material.

It is provided in further development of the invention that the semiconductor substrate is highly doped in its surface bordering on the first and/or second contact, for example, by diffusion, and/or is inverted and/or has a hetero transition.

The first contact collecting the minority charge carrier (emitter contact) can be a metal/semiconductor and/or a MIS (Metal Insulator Semiconductor Contact).

A metal contact applied directly on the semiconductor substrate and/or a metal contact applied on a highly doped semiconductor substrate can be [used] as a second contact (base contact) collecting majority conduction carriers.

In other words, the semiconductor surface can, beside the contacts a) be highly doped (preferably by diffusion or ion implantation; for example n⁺-type layer with p-type semiconductor), b) inverted (electron inversion layer with p-Si), c) possess a hetero-transfer (e.g., a-Si/p-Si) or d) be passivated by a corresponding surface layer.

a) Metal semiconductor contacts, whereby preferably the semiconductor is highly doped in the contact region (n⁺ with p-Si), b) corresponding metal insulator semiconductor contacts (MIS), whereby the semiconductor under the metal can be highly doped (MI n⁺p) or only be inverted through a suitable metal due to an electronic work function difference (preferably Al at p-So) (R. Hezel, R. Meyer, A. Metz, Solar Energy Materials and Solar Cells 65, p. 311 (2001)).

Metal contacts, for example, can be used directly on the semiconductor (for example Al-p-Si, Ti—Pd-Ag-p-Si or metal contacts on highly doped semiconductors (for example, Al-p⁺-Si) as majority charge carrier contact, whereby the p⁺ region serving as local “Back Surface Field” (BSF) can be generated by diffusion, ion implantation (for example, of boron) or even by alloying the Al with silicon (“Al BSF”). A laser or lamp irradiation using the shadowing effect taking place under a shallow angle (preferably 1°-30°) can be relied upon for the alloying process in accordance with the invention. In this way, only the contact region is selectively heated.

In this way, the formation of the second contact can be simplified in that, for example, aluminum fingers are applied by oblique evaporation deposition onto the passivation layer and heat is locally applied with the laser. In this fashion, the aluminum penetrates the passivation layer and forms an ohmic contact toward the semiconductor substrate.

According to a refinement of the invention, a passivation material is extended over the entire back surface of the semiconductor substrate, including the elevations, thus over the semiconductor as well as over the first and second contacts so that the charge carriers generated by the light diffuse directly to the first and second contacts on the back.

Moreover, according to a further development of the invention, the passivation layer can consist of a double or multiple layer with an a-Si— layer, such as a-Si:H layer running on the substrate side, on which at least one layer is arranged, preferably of plasma SiN, SiN or SiO₂. The passivation layer should especially indirectly or directly prevent or basically prevent a charge carrier transport between first and second contact.

In a further refinement, a highly doped n-type layer (n⁺) or an n-type conducting inversion layer (for example, a hetero-transition) is generated by positive charges in the passivation layer along which the minority charge carriers can flow to the first contact.

In accordance with a further proposal, first the passivation material is applied over the entire area, and then the first and second contacts are arranged on the semiconductor substrate surface having the elevations such that the first and second contacts are arranged on exterior segments of the elevations at least regionally previously covered with passivation material and then freed of this, directly or on an insulation layer, and such that either a passivation layer without generating a cross conductivity, a conducting inversion layer or a highly doped n⁺ type layer generated preferably by diffusion or ion implantation extends along the semiconductor substrate extends in the case of a p-doped semiconductor substrate.

The contacts are arranged linearly in the entire longitudinal flank region, preferably, however, in the upper part on both sides of the elevations, whereby the metal can run partially on the semiconductor directly and partially on the passivation layer.

The semiconductor surface can also be provides in the overall area with a texture, such as small pyramids, from the tips of which the passivation layer and in part semiconductor material are removed in the contact region of the elevations. Metal contacts are applied over this through oblique evaporation deposition. In contrast to the previously described pure line contacts, it is a matter of a point contact system connected preferably through an inversion layer or n⁺-type layer which is covered over by the linear contact (metal finger). The point contacts possess a square form and can be used to collect minority and majority charge carriers.

In order to ensure that basically all minority charge carriers reach over the minority charge carrier discharge layer designated as emitter layer to the first contacts, as the contacts or emitter contacts collecting the minority charge carriers, a refinement of the invention to be accentuated provides that the elevations have a breadth B in their semiconductor substrate base which is maximally doubled diffusion length of the minority charge carriers in the semiconductor substrate. The base consequently forms a directive valve for the minority charge carriers through which the latter are guided to the first contacts and kept from the second contacts. Obviously other dimensions are possible.

Quite generally the shape of the elevation should be selected such that first and second contacts proceeding from an elevation with their respective elevation base-side longitudinal edges span a first plane and that between the first plane and the semiconductor layer-side base of the elevation, a sectional plane intersecting with the longitudinal flanks running in a plane spanned parallel by the semiconductor substrate has a width B which is smaller than or equal to double the diffusion length of the minority charge carriers in the semiconductor substrate.

In particular, the distance between the base-side edge of the second contact and the base of the elevation should be greater than half the breadth of the base. Through these measures, it is assured that if an emitter layer runs along the surface of the elevation that majority/minority charge carrier pairs generated in the elevations will also be selectively led away such that the minority charge carriers are discharged directly to the first contact or to this through the emitter layer.

A basic feature of the invention consists in that an n⁺-type layer or an inversion layer is situated on the base-side shoulder of the elevations on both flanks that sucks off the minority charge carrier so that they cannot diffuse to the deeper lying p⁺-type contact (majority carrier contact) and recombine there. The p⁺-type contact is consequently screened off. The configuration of the invention brings about an increase of the degree of efficiency as well as a possible simplification of the process, since a p⁺ doping under the metal (local back surface field) can be dispensed with.

A method of the type mentioned at the beginning is distinguished in that the first trenches of the back are constructed with trench bottoms and the elevations of the back with exterior segments which run parallel to the plane spanned by the by the semiconductor substrate, in that on at least some of the elevations, the first electrical contacts are applied on the first longitudinal flanks of the elevations and the second electrical contacts on the second longitudinal flanks of the elevations such that the first and second electric contacts are spaced from one another on the trench bottom side as well as exterior segment side. In particular, the first and/or second contact are applied by evaporation deposition of material under an angle α toward the plane spanned by the semiconductor substrate proceeding from the normal, whereby the evaporation angle α amounts to α≠0° and α≠90°. In the process the first contacts are formed or reversed with a first inclined vacuum evaporization process step, and then the second contacts in a second inclined vacuum evaporization process step. The angle α preferably amount to 89°>α>60°≈ Basically, however, first of all the contacts collecting majority charge carriers (hence the ohmic contacts collecting the holes in the case of a p-type substrate) are manufactured and subsequently the contacts collecting the minority charge carriers.

Ions are implanted free of masking for doping the first and/or second longitudinal flanks, especially beneath first and/or second contacts to be constructed on these such that these occur under an angle of incidence β toward the normal whereby angle of incidence β≠0° and β≠90°. Angle β preferably amounts to 89°>β>60°.

Furthermore, the invention provides that the back surface of the semiconductor substrate is covered over the whole surface or basically over the whole surface with a passivation layer and then preferably at least the passivation layer and if need be the semiconductor material in the free longitudinal edge region of the elevations as well as in particular their plateau-like outer regions are removed, preferably by chemical-mechanical polishing.

After removal of the passivation layer, the first and second contacts can then be constructed, whereby if need be the first and/or second contact run regionally elevation side on the passivation layer.

Whether it be for separation of the first and second contacts running along the front surfaces of the elevations or for wearing down the passivation layer material on the elevations, be it in the region of free external longitudinal edges of the elevations, then it is suggested for this purpose in accordance with the proposal of the invention, which is quite generally usable for semiconductor elements, that a polishing element with a translatory motion or a rotary motion, such as a polishing plate, be used when polishing, especially during mechanical-chemical polishing of the back surface of the semiconductor substrate, whereby the semiconductor substrate is oriented on the polishing element such that the elevations are oriented with their longitudinal direction in the direction of travel of the polishing element. In the case of a rotating polishing element or a polishing element moving with a translatory element, the long axes of the elevations should enclose an angle γ with in particular 1°≦γ≦30° toward the direction of motion of the polishing element. A parallel orientation is nonetheless likewise possible.

According to proposals of the invention to be stressed, it is accordingly suggested that the first and second contacts be arranged, either over their entire width or at least regionally, directly on segments of the elevations or on an insulation layer, and that the semiconductor substrate surface be covered either by a passivation layer (SiO₂, SiN, Al₂O₃, a-Si, a-Si:H, etc.) or that electively, a doped layer leading the minority charge carriers to the contacts, a hetero-layer or an inversion layer additionally extends along the semiconductor substrate surface, which can generally be designated as a minority charge carrier lead or emitter layer.

Further particularities, advantages of features of the present invention emerge not only from the claims, the features to be gathered from these (by themselves and/or in combination), but also from the following description of a preferred embodiment to be gathered from the drawings, wherein:

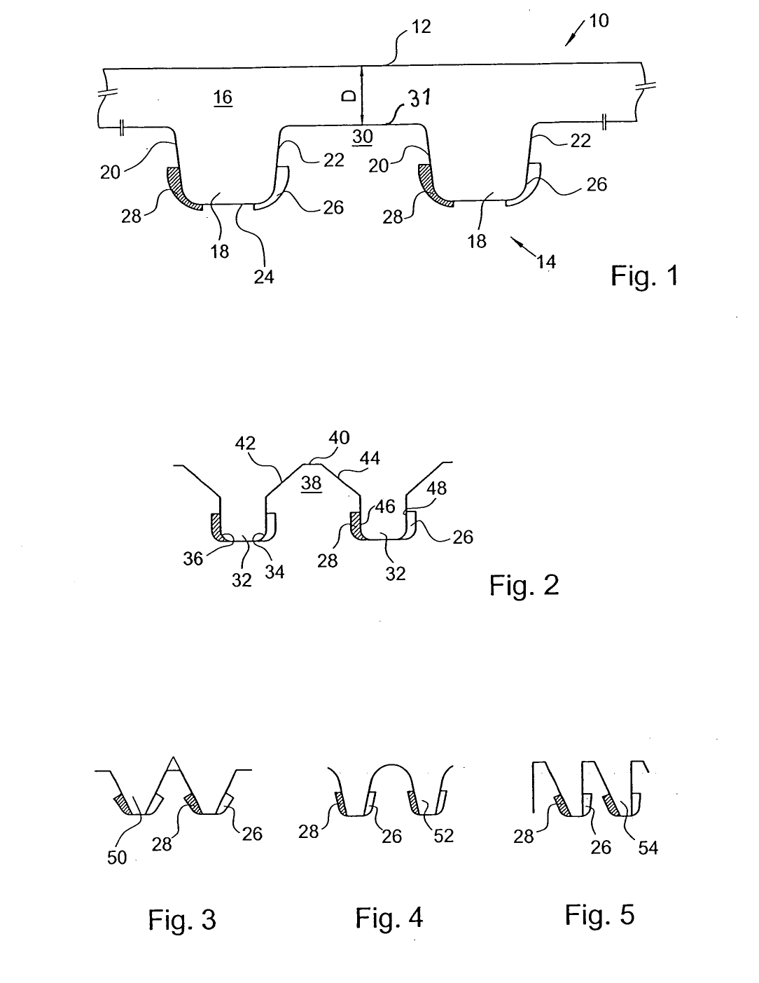

FIG. 1 Is a basic representation of a solar cell with back elevations,

FIG. 2 to 5 Illustrate refinements of back elevations of a solar cell,

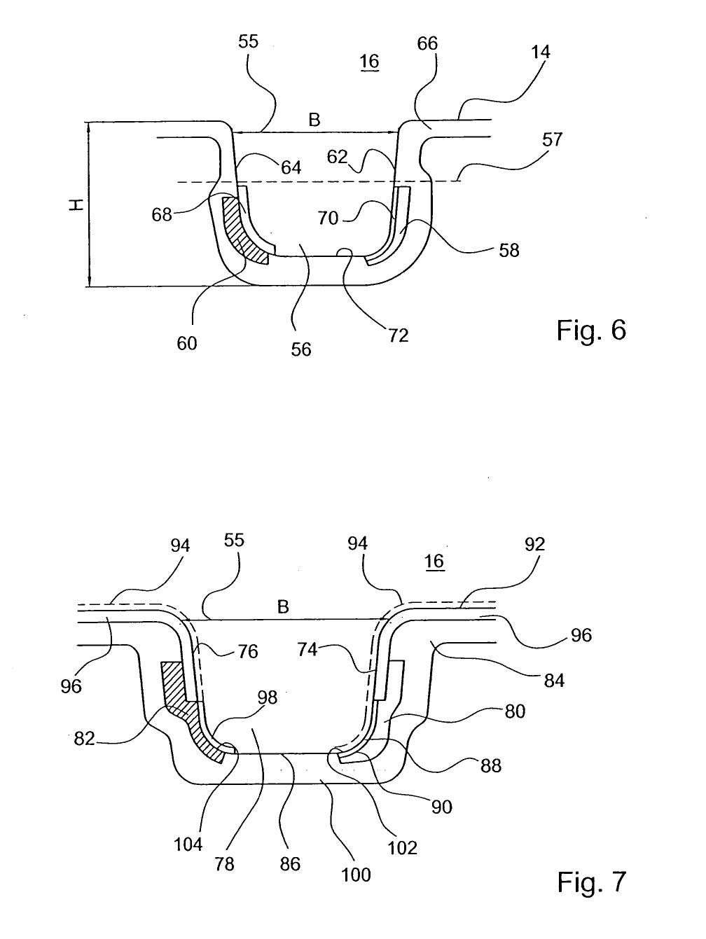

FIG. 6 Illustrates a first embodiment of back contacts of a solar cell,

FIG. 7 Illustrates a second embodiment of back contacts of a solar cell,

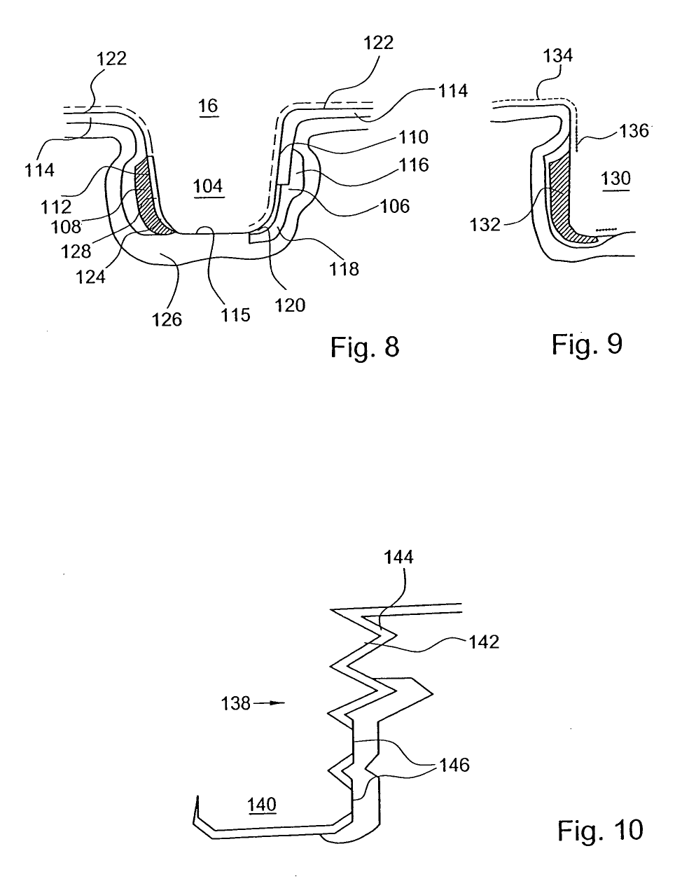

FIG. 8 Illustrates a third embodiment of back contacts of a solar cell,

FIG. 9 Illustrates a cut out of a back elevation of a solar cell with a contact and

FIG. 10 Illustrates a back elevation of a solar cell with texturing.

Various embodiments and refinements of solar cells can be gathered from FIGS. 1 to 10 in which the minority as well as the majority charge carriers are collected on the back.

The theory of the invention is moreover quite generally applicable for solar cells. Here a realization should be based, for example, on p-n-type transitions generated by doping and heterostructures as well as on influencing an electric field through a metal or through surface insulator charges. Semiconductor materials which come into question are n-type or p-type conducting monocrystalline, polycrystalline or amorphous materials and element or connection semiconductors. Moreover a doping with gallium, indium or aluminum should be used for the case of crystalline silicon in addition to boron and phosphorous doping. The use of thin layer semiconductors such as copper-indium-selenide or sulfide, cadmium telluride and gallium arsenide is likewise possible.

It is moreover provided in accordance with the invention that the contacts collecting the minority and majority charge collectors which can subsequently be designated as first and second contact or emitter and base contact are designed for the back of solar cells, have as small contact surfaces as possible for attaining high open circuit voltage, are well surface-passivated and can be simply manufactured. Put generally, for this purpose, the corresponding contacts are preferably produced free of masks and adjustment by oblique evaporation deposition in a vacuum while using the shadowing effect (R. Hezel, Proc. 13^{th} European PVSEC, Nice, p. 115 (1995)). The front side should preferably possess no contacts, but should be textures and have a very good passivation layer and anti-reflex layer. The semiconductor substrate can be doped over its entire area (n⁺ or p⁺), owing to which a “floating junction” is formed. The front can also electively be provided with an additional contact system collecting minority charge carriers.

Structures with intermeshing MIS and ohmic contacts are to be discussed in the embodiments purely by way of example. These can also be replaced by other contacts without leaving the invention.

Furthermore, in explaining the embodiments, a p-type doped semiconductor material serves as the point of departure without this being understood as restrictive. With another base material, if need be other conductors or dopings must be used to attain the desired field conditions.

The solar cell 10 with front side 12 and back 14 is very basically represented in FIG. 1. A p-type conducting material is used as semiconductor substance 16. The back 14 of the solar cell 10 has strip or bar-like elevations 18 with longitudinal flanks 20, 22 which pass over into each other through a plateau-like running outer segment 24 which runs parallel or basically toward the plane spanned by semiconductor substrate 16.

Basically each elevation 18 has a first contact or emitter contact 26 as well as a second or base contact 26, whereby each contact 26, 28 extends at least segment-wise along the longitudinal flanks 20, 22 and if need be regionally along the plateau-like outer segment 24.

In other words, the first contacts 26 collecting minority charge carriers are situated on one flank of elevation 18, which is designated as the first longitudinal flank 22, and the second contact 28 collecting the majority charge carriers is situated on the opposite flank of the same elevation 18, which is designated as second longitudinal flank 20.

A trench 30 runs between the elevations 18 on the bottom side can run parallel to the plane (trench bottom 31) spanned by the semiconductor substrate 16 or inclined toward the latter, as is made clear on the basis of FIG. 2 through 5. Of course, the trench bottom should run at least segment-wise parallel to the plane.

Thus a cutaway of a solar cell is reproduced in FIG. 2 in which elevations 32 rectangular in section with longitudinal-side rounded off edges 34, 36 are connected through a trench 38 trapezoidal in section which is bounded by a narrow bottom surface 40 (trench bottom) running parallel to the plane spanned by the semiconductor substrate 16 as well as sections 42, 44 running inclined toward this.

The construction of a texture in the trench region can largely be avoided by the inclined sections 42, 44, since in this region the crystal planes (100) necessary for the generation of pyramid through an anisotropically acting texture etch are not present.

Furthermore, it is advantageous (as elevations 18, 32 make clear) if their longitudinal flanks 20, 22 or 46, 48 run perpendicular or almost perpendicular to the plane spanned by the semiconductor substrate 16, since in addition to a support function, it is ensured that a texture exists arising if need be only in the region of the contacts 26, 28 proper, which are designated with the reference numbers 26, 28 in the embodiments of FIG. 1 to 5.

Avoiding a texture and in this way a surface enlargement on the back 14 of the solar cell 10 is advantageous for diminishing the charge carrier combination disadvantageous for efficiency.

Other embodiments of elevations 50, 52, 54 emerge from FIG. 3 to 5. One will recognize elevations 50, 52 or 54 V, U or sawtooth-like in section on whose respective longitudinal flanks the first and second contacts 26, 28 are arranged.

Regardless of the shape, it is recognizable that the trench region running between the elevations 50 or 52 or 54 basically has a bottom surface which is oriented toward the plane spanned by the semiconductor substrate to avoid a texture in this region as mentioned which would led to an undesirable surface enlargement and in this way to increasing the charge carrier combination. Regardless of this, the mid region runs at least segment-wise along the plane, just as FIG. 3 also makes clear another embodiment with which the theory of the invention can be realized.

To the extent that a first and second contact is situated on each of the elevations, there results an equal number of emitter and base contacts. Of course, it is not absolutely necessary for all elevations to be occupied on both sides by contacts.

Thus, for example, several elevations provided on one side with first contacts 26 can lie side by side and follow at certain distances to these elevations of the invention with first and second contacts 26 or 28. In this case, more first contacts 26 would be present than second contacts 28, whereby the latter have a greater distance from one another than the former.

Basically the contacts 26, 28 or their metal layers are formed by evaporation deposition. The metal evaporation deposition takes place here generally selectively first from the one and then from the other side of the elevations and indeed under an angle running flatly toward the plane spanned by the semiconductor substrate which can lie between 1° and 30°. Consequently the contacts 26, 28 or their metallizations cover the longitudinal flanks regionally entirely.

As mentioned, the shape of the elevations is variable in wide limits, whereby vertical, oblique or rounded off longitudinal flanks are to be mentioned as preferred.

A preferred first embodiment of a contact arrangement arranged on a back side elevation 56 of a solar cell is represented in FIG. 6, which in accordance with the invention has a first contact collecting and discharging a first minority charge carrier as well as a contact 60 collecting and discharging a majority charge carrier.

The first and second contacts 58, 60 extend along the first and second longitudinal flanks 62, 64 of the elevations which for their part are constructed in the form of lines and strips and run parallel to each other.

It is furthermore recognizable from FIG. 6 that a layer 66 extends along the back 14 of the semiconductor body 16 in the form of a passivation layer which if need be can also cover over the first and second contacts 58, 60. Alternatively, the passivation layer 66 can also be recessed in this region. With the first alternative, the first and second contacts 58, 60 are first constructed on the longitudinal flanks 62, 64 and subsequently the passivation material is deposited at temperatures at which the contact properties between the first and second contacts 58, 60 and the first and second longitudinal flanks are not altered disadvantageously.

If the passivation layer 66 is to be constructed at high temperatures, then (as will be explained below) openings must be constructed in the latter for subsequent applications of the first and second contacts 58, 60.

Since the charge carriers (minority or majority charge carriers, electrons or holes) predominantly diffuse directly to the contacts 58, 60, a layer 68 repelling the minority charge carriers and therewith a local “back surface field” (BSF) should be generated in the region of the second contact 60 collecting the majority charge carriers. In the event of a p-type doped semiconductor substrate, it is a matter of a layer 68 with preferably a p⁺-type layer. This can, for example, be constructed by the known alloying of Al (Al-BSF) or by diffusion or by ion implantation.

In the embodiment, the first contact 58 is constructed as a MIS contact with a very thin tunnel insulator layer 70 which, for example, can be replaced by an n⁺-type metal contact manufactured by phosphorus diffusion or ion implantation (even in connection with a tunnel insulator layer →MI n⁺p).

The manufacture of the corresponding contact arrangement can be undertaken as follows:

After passivation of the front of the solar cell by a layer manufactured at the optimal separation temperature, the second or ohmic contacts 60 are applied to the lateral second longitudinal flanks 64 of the elevations 56 preferably by oblique evaporation deposition of aluminum in a vacuum and then metal deposited on the plateau-like segments 72 of the elevations 56 is eliminated by etching or another method (for example by chemical-mechanical polishing). The ohmic contacts 60 are formed and the tunnel insulator or tunnel oxide layer 70 for the MIS contacts or the first contacts 58 are generated by a subsequent tempering in oxygen at ca. 400° C.-500° C.

To increase the electronic work function between the semiconductor substrate (e.g. p-Si) and the metal (for example Al) of the MIS contacts 58, a preferably alkaline metal-containing substance (for example CsCl) can be applied immediately before applying the metal on the tunnel oxide layer preferably by oblique evaporation deposition in a vacuum as well. Oblique evaporation deposition of the metal (preferably aluminum) for the MIS or second contacts 58 (preferably aluminum) and etching away the excess metal on the plateau-like segments 72 running between the longitudinal flanks 62, 64 follow. Finally the entire back 14 is covered with the passivation layer 66, preferably plasma silicon nitride. The formation of an inversion layer in p-Si should be avoided to prevent short circuits, among other things. This can be ensured in that preferably a passivation double or multiple layer is applied or formed on the semiconductor substrate, whereby an Si:H layer if need be but a few atom layers thick, and then at least a further layer such as SiN, plasma SiN or SiO₂ runs on the substrate side. Of course an a-Si:H layer alone could also suffice as passivation. In addition, a reflecting metal, for example Ag or Al, can also be applied over the entire back side as a so-called back side mirror in order to guide the light not absorbed in the semiconductor back into this to increase current.

In accordance with the invention, the layer 68 (p⁺ region) generating the local electric field of the majority charge carrier 60 as well as a p-n minority charge carrier contact (n⁺ region) instead of the MIS contact 58 explained in FIG. 6 can be generated by the oblique ion implantation method. Here, as in the case of oblique evaporation deposition of the metal in a vacuum for the contacts 58, 60, the self-shadowing brought about by the elevations is used to implant, for example, boron or phosphorus ions free of masking and adjustment or in the entire flank region under a very obtuse angle toward the semiconductor surface (=plane spanned by the semiconductor substrate 16 which runs parallel to the front surface 12 of the solar cell). The angle lies preferably in the range between 1° to 30°.

Following an annealing temperature process, the local application of the metal can take place, preferably by oblique evaporation deposition in a vacuum, likewise free of adjustment and masks.

Through a very dense, almost parallel arrangement of semiconductor substrates in an implantation facility, the profitability of conventional ion implantation is drastically increased (cf. oblique evaporation deposition method)(R. Hezel and A. Metz, Renewable Energy 14, p. 83-88(1998)).

A cutaway of an additional embodiment of a solar cell 10 to be emphasized can be derived from FIG. 7 in which first and second contacts 80, 82 extend on first and second longitudinal flanks 74, 76 of back side elevations 78 of a semiconductor substrate body 16, which extend partially on material of the semiconductor substrate 16 and partially on a passivation layer 96, that runs on the back of the semiconductor substrate 16.

In accordance with the theory of the invention, the first and second contacts 80, 82 run on the opposed first and second longitudinal flanks 74, 76 of the elevations 78 and are spaced from one another in the region of the plateau-like outer segment 86. The plateau-like outer segment 86 or region corresponds to the outer segments of elevations 18 or 56 provided with reference number 24 in FIG. 1 and 6. Furthermore, the first and second contacts 80, 82 run at a distance to the trench bottom, in the embodiment at a considerable distance from the rim of the trench bottom.

A metal insulator semiconductor (MIS) arrangement with a thin tunnel oxide is selected for the first minority charge carrier collecting contact 80 in accordance with FIG. 6, preferably in the form of an alkaline metal-containing layer 88 between the external metal layer 90 and the semiconductor substrate.

A minority charge carrier discharge layer 94 extends beneath the MIS contact 80 so formed and on the remaining back surface 92 of the semiconductor substrate 16, which can also be designated as the emitter layer 94.

In the event of the p-type conducting semiconductor as a semiconductor substrate 16, the emitter layer 94 can be an n-type conducting inversion layer which is formed by positive charges in the passivation layer 96 of a diffused or ion-implanted n⁺-type layer. The passivation layer 96 here runs along the surface 92 of the semiconductor substrate 16 and is partially interrupted in the region of the first and second contacts 80, 82.

The emitter layer 94 should be separated as to potential from the second contact 82. The emitter layer 94 preferably ends spaced from the second contact 82 to prevent minority charge carriers from recombining on the second contact and consequently a short circuit between the first and second contact 80, 82 taking place.

It is basically advantageous to have the emitter layer 94 or n-type conducting layer end in the immediate vicinity before the second contact 82 under the passivation layer 96 and/or to insert a barrier layer between the n-type conducting layer 94 and the second contact 82 to separate the first and second contacts 80, 82 (or emitter and base contacts).

Alternatively, a local back surface field (BSF) 98, as this has been explained in connection with FIG. 6, can also be formed along the substrate side side of the second contact 82 and laterally on both sides over the region of the semiconductor substrate 16 covered by the metal of the second contact. In this way, a potential barrier arises between the n-type conducting layer or emitter layer 94 and the p-type conducting BSF layer 98 which largely prevents a outflow of minority charge carriers or electrons to the majority charge carrier contact 82.

In the case of an inversion layer as an emitter layer 94, a local BSF layer 98 is likewise advantageous even if a potential barrier is present on the second contact 82 even without the formation of the BSF layer 98 which largely prevents the outflow of the minority charge carriers (electrons) in the majority charge carrier contact 82 (R. Hezel and K. Jaeger, J. Electrochem. Soc. 136, 518 (1989)).

The emitter layer can preferably be constructed by phosphorus diffusion and the local backfield preferably by alloys of aluminum and indeed together in a single thermal operation. A process engineering simplification results in this way.

Finally, a second passivation layer 100 is situated over the entire back 14 over which another metallic layer can be deposited as light reflector (Back Surface Reflector). The passivation layer 100 should basically prevent an inversion layer from arising, since otherwise there would exist the danger that a short circuit would arise between the respective first and second contact 80, 82.

Quite generally, it should be pointed out that the passivation layer should directly or indirectly (for example, by forming an inversion layer) ensure that a charge carrier transport between the first and second contact is prevented or basically prevented.

With the embodiment represented in FIG. 7, the charge carriers generated by light reach the first contact 80 over a highly doped n⁺-type layer extending almost over the entire back 14 of the solar cell or over an n-type conducting inversion layer 94 through positive charges in the passivation layer 96 in the semiconductor or the semiconductor substrate 16. Preferably silicon nitride separated in plasma and containing positive charges, should be used as a passivation layer 96 through which at the same time the inversion layer 94 is generated in the semiconductor. The inversion layer 94 (for example, in p-silicon) is partially influenced by natural positive charges arising on the insulator semiconductor boundary layer, but can be still basically improved in its conductivity by increasing the positive charge density, preferably by incorporating alkaline metal-containing substances in the silicon nitride (passivation layer 96) at a small distance (1-10 nm) from the semiconductor surface 92. Another thin insulator layer (for example, SiOx of a thickness of 1 nm-10 nm) can be incorporated between the silicon nitride layer and the semiconductor.

The previously described arrangement forms a backside whole-area collecting solar cell. In contrast to the theory to be discerned from FIG. 6, the charge carrier pair (minority and majority charge carriers) are separated by inversion layer 94 or n⁺-type layer with connecting space charge zone extending almost over the entire back 14, and indeed long before these reach contacts 80, 82. The holes (majority charge carriers) diffuse in the elevated regions (elevations 78) toward the laterally arranged second or ohmic contacts 82. The electrons (minority charge carriers) in contrast all collected at the entry of the elevations 78 of the emitter layer or inversion layer or n⁺-type layer 94 running on both sides in the event that the breadth of the elevations 78 is smaller than double the diffusion length of the electrons, so that the former cannot reach the majority charge carrier contact 82 and recombine there. The majority charge carrier contact 82 is accordingly (in contrast to all known solar cells) almost exclusively exposed to majority charge carriers.

The arrangement in accordance with the invention of contacts 80, 82 on elevations opposite one another and surrounded with a conductive layer 94 (n⁺, inversion layer, etc.) therewith assures a most highly efficient separation of the charge carriers even in the region of the contacts 80, 82 in a simple geometric matter.

In addition (as drawn in FIG. 6 and 7 for the majority charge carrier contact region), locally diffused, alloyed or ion-implanted regions (n⁺) can be applied for the minority charge carrier contact 80.

With regard to contact manufacture, according to FIG. 7, the first and second contacts 80, 82 are arranged regionally on segments of elevations 78 previously covered with passivation material and then freed of this directly or on an insulation layer. For this purpose, the entire semiconductor substrate surface 92 is covered with a passivation layer 96 preferably optimized for the lowest surface recombination speed and if need be provided with an alkaline metal-containing substance for increasing positive boundary layer charges. Then the passivation layer 96 and regionally the semiconductor material are applied preferably by chemical-mechanical polishing (CMP) in the upper flank region (longitudinal rims 102 and 104 of the first and second longitudinal flanks 74, 76) and on the surface of the plateau-like outer segment 86 of the elevations 78, whereby the formation of rounded edges can occur. Subsequently metal for forming the ohmic contacts 82 is deposited respectively on one side of the elevations 78 (second longitudinal flank 76) preferably by oblique evaporation deposition in a vacuum. A heat treatment (tempering) at 400° C.-500° C. takes place thereafter for formation of the ohmic contacts 82, whereby through the administration of oxygen, tunnel oxide (layer 88) is formed at the same time on the semiconductor surface 92 on the opposite side (first longitudinal flank 74) of elevations 78 previously freed of passivation layer 96. Then a thin layer of a material with low electron work function is applied to the tunnel oxide, preferably alkaline metals or their compounds, in order to increase the electronic work function difference between the metal (layer 90) and semiconductor (substrate 16). The first contact 80 formed as MIS contact is completed by oblique evaporation deposition of metal (layer 90) on the upper part of the first longitudinal flank 74, whereby the layer 90 in the lower region of the longitudinal flank 74 also runs regionally on the passivation layer 96. In the upper part, thus in the longitudinal edge side region, the metal and therewith the MIS contact 80 can still extend regionally over the rounding (longitudinal edge 102) toward the exterior segment 86 of the elevations 78 connecting the longitudinal flanks 74, 76.

An exact separation of the two contacts 80, 82 in the plateau-like segment 86 of the elevations 78 and therewith avoiding a short circuit of the solar cell is of decisive importance. In the end, the entire back is coated once again with a passivation layer (layer 100) in order to cover exposed semiconductor substrate surfaces (segment 86) on the elevations 78 between the first and second contacts 80, 82 and for preventing short circuits. The formation of an inversion layer in the semiconductor should moreover be avoided. In addition, the application of a back mirror is possible.

The fact that the metal deposited during oblique evaporation deposition even on the plateau-like segment 86 of the elevations 78 connecting the first and second contacts 80, 82 and therewith short circuiting the cell can be removed in a simple manner is also of particular importance. A deciding feature of oblique evaporation deposition is namely that the deposited metal arising under a small angle on the surface is for one basically thinner that on the longitudinal flanks 74, 76 for the contacts. Second, the metal grows loose on the basis of its stalk construction so that this can already be eliminated by a short etching process. In this way, the thickness of the metal (metal finger) on the longitudinal flanks 74, 76 is but insignificantly diminished.

Alternatively, the metal deposited in oblique evaporation deposition on segments 86 of the elevations 78 can be removed mechanically or by chemical-mechanical polishing (CMP). The n⁺-type layer arising on the plateau-like segments 86 of the elevations 78 during diffusion, which connects the two contacts 80, 82, for example, is also eliminated with this selective method. In this way, a very good separation between emitter and base contacts, thus the first and second contacts 80, 82, is guaranteed. By removing the conducting layer it is assured that a short circuit between the first and second contact is ruled out.

A characteristic proposal of the invention is to be seen in the measure of removing the passivation layer 96 and as little semiconductor material as possible regionally from the longitudinal flanks 74, 76 of the elevations 78 using chemical-mechanical polishing (CMP), in order to be able to apply the metal contacts 80, 82 there on one side, if possible, however, on both sides of the elevations 78, preferably by oblique evaporation deposition in a vacuum. This local removal in the upper part of the flank region takes place in accordance with the invention in that the semiconductor substrates 16 provided with trenches bounding the elevations 78 do not rotate on the polishing plate, as is typical with CMP and also, for example, was carried out only from the upper side of elevations in DE 41 43 083 A1 for removal of the passivation layer, but is held fast in a specified position. In addition, the positioning takes place according to the theory of the invention that the trenches come to lie almost parallel, thus under a relatively small angle γ toward the direction of motion of the polishing element such as the rotating polishing rag, owing to which an unimpeded flow of the polishing agent toward the flanks is made possible. A so-called oblique polishing takes place. In this way, a relatively high polishing force acts upon the respective longitudinal flank of the elevations so that the lateral wear speed of the passivation layer 96 and semiconductor material and therewith the contact opening in relation to the rate of wear on the surface (segment 86) of the elevations 78 is optimized. An angle range from 1° to 30° between the polishing direction and the trenches or elevations 78 might be especially recommendable. A polishing direction with rotating element such as a disc as well as a linear polishing arrangement, thus translatory movement back and forth or linear motion, can be used. In all cases, a rounding of longitudinal edges 102, 104 of the elevations 78 occurs.

In accordance with the invention, the local removal of the passivation layer can be avoided in the contact region in that a protective layer is applied before deposition of the passivation layer in the later contact region in the upper part of the flanks and (in the event that it cannot be avoided) on the elevations as well, for example by rolling pressure or a dipping process or by oblique evaporation deposition or the like. In this way, no passivation layer is deposited on the semiconductor in these regions. The protective layer is removed together with the passivation layer lying above it and the contact metal is preferably applied by oblique evaporation deposition in a vacuum.

Additional features of the theory of the invention enjoying independent protection can be derived from FIG. 8 to the extent the back contact region is affected. Hence, in FIG. 8 a cutaway of a solar cell in the region of an elevation 104 is represented which proceeds from the back of a solar cell. Moreover the solar cell has (as in the embodiments of FIG. 1 to 7) a large number of strip-like or bar-like elevations 104 running parallel to one another which are accordingly bounded by trenches which have been explained in connection with FIG. 1 to 5. This also applies in particular to the selective construction or suppression of a texture. Moreover the trenches preferably have trench bottoms running parallel to the plane spanned by the semiconductor substrate which are uncovered by electrically conducting contacts.

First and second contacts 106, 108 are likewise provided with the contact arrangement according to FIG. 8 which run on the first and second longitudinal flanks 110, 112 of the semiconductor substrate 16 of the solar cell. Moreover the contacts 106, 108 proceed from the same elevation 104 and are spaced from one another in the region of their free plateau-like running surface 114, this in the outer segment of elevation 104.

In deviation from the embodiment of FIG. 7, a passivation layer 114 does not extend beneath the second or majority charge carrier contact of base contact 108. Rather the second contact is arranged directly on the semiconductor substrate 16, and to be sure on its second flank 112. In contrast, the first or minority charge carrier contact 106 is arranged on the passivation layer 114 in the region 116 lying near the base of elevation 104, in contrast to which the remaining longitudinal rim-side region 118 is arranged directly on the semiconductor substrate or on an insulation layer 120, as was explained on the basis of FIG. 4.

So that the first contact 106 runs but regionally along the passivation layer 114, the passivation layer 114 running along the right longitudinal flank 110 represented in the figure is first of all partially removed. Then the first contact 106 is formed which as mentioned runs partially on the semiconductor material, partially on the passivation layer 114. Moreover, in the case of an MIS contact, layer 120 is constructed, for example, in the form of a tunnel oxide layer on the semiconductor as a first contact 106.

In accordance with the feature characterizing the embodiment of FIG. 7 in particular, an emitter layer 102, such as an n-type inversion layer or an n⁺-layer generated by preferably diffusion or ion implantation moreover extends along the semiconductor surface 122. In addition, a local BSF layer 124 can be applied beneath the second contact 108. Finally the entire back 14 of the solar cell can be covered with a second passivation layer 126, which consequently also extends over the first and second contacts 106, 108.

The appropriate contact arrangement of the invention is manufactured as follows:

After constructing the elevations 104 on the semiconductor substrate 16, the second contact 108 is first applied on the second longitudinal flanks 112 of the elevations 104, especially by oblique evaporation deposition in a vacuum. A BSF layer 128 can be constructed electively by an Al alloy or previously by a boron implantation whose areal extension is selected such that the longitudinal rims of the second contact 108 extend on the BSF layer 128. Then the passivation layer 114 is deposited over the entire back side, preferably in the form of silicon nitride, whereby preferably previously a thin insulation layer with a thickness between 1 nm and 10 nm is generated on the semiconductor surface which is coated with a substance generating positive charge, preferably an alkali metal or compounds of this. In this way the desired emitter layer (for example, n-type conducting inversion layer or n⁺ layer) extending over the entire semiconductor surface is formed, along which the minority charge carriers (electrons) reach the first contact 106. The passivation layer 114 is regionally removed for applying the minority charge carrier contacts 106, preferably by oblique polishing. Then follows a temperature treatment with oxygen administration at 400° C. to 500° C., through which on the one hand the second contacts 108 or ohmic contacts are formed, and on the other hand, the tunnel oxide layers 120 which are necessary for the first contact 106 formed as an MIS contact in the embodiment grow. Then the metal necessary for the first contact 106 is applied on the exposed areas of the first longitudinal flanks 110, partially on the passivation layer 114, preferably likewise by oblique evaporation deposition. Finally the entire back is covered with the second passivation layer 126, owing to which the uncoated region of the plateau-like segment 115 or the outer 30 segment of the elevations 104 is passivated, owing to which once again the desired electrical separation between the first and second contacts 106, 108 is guaranteed. Quite generally silicon oxide, silicon nitride, aluminum oxide, amorphous Si:H etc come into question as passivation materials. Preferably a multiple layer system, for example, of an a-Si:H layer running substrate side and a layer running above this such as plasma SiN, SiN or SiO₂ is selected to avoid the formation of an inversion layer in the plateau-like region 115 of the p-type semiconductor substrate.

In order to avoid a short circuit, it is advantageous if the emitter layer (inversion layer or n⁺-type layer) 122 does not extend directly to the second contact 108, to the extent that a layer 124 generating a local backfield is lacking in the region of the second contact 108. This is especially significant with the presence of an n⁺-type layer as emitter layer 122.

With regard to the first, thus minority charge carrier collecting contact 106, it is provided that either the emitter layer 120 is continued under contact 106 or a phosphorus-diffused or implanted n⁺-type region, for example, is applied beneath contact 106.

Consequently an inversion layer as well as a local n⁺-type layer on the first contact 106 (n⁺p contact) can border on an inversion layer as emitter layer in the non-contact region. Obviously a continuous n⁺-type layer, which is to be covered over with the first contact by the tunnel oxide layer 120, is possible (MI n⁺p).

The following is to be supplementally stated on FIG. 6 to 8. The emitter layer 94, 122 must also be present in the plateau range 86, 115 in FIG. 7 and 8. The emitter layer 94, 122 must be at a distance from contact 82, 108 to avoid a short circuit, or blocked by the backfield 98.

In FIG. 6, a highly doped n⁺-type conducting inversion layer can extend over the entire back 14, including the plateau region 72 (with the exception of the back field region 68 of contact 60), similar to FIG. 7 and 8, owing to which a charge carrier collection takes place in the entire back region.

An embodiment of an elevation 130 on the back of a semiconductor substrate can be derived from FIG. 9, in which a local BSF region is not situated beneath a second, majority charge carrier-collecting contact 132. In order nonetheless to prevent an outflow of the minority charge carriers from an emitter layer extending along the semiconductor substrate surface such as inversion layer 134 in the second contact 132, an accumulation layer 136 can be generated between the second contact 132 and the emitter layer 134 which forms a potential barrier as a “channel stopper.”

To the extent that aluminum is used as metal for the second contact 132, the potential barrier can be formed by oxidation of the aluminum into aluminum oxide which contains negative charges on its boundary to the semiconductor substrate such as silicon which leads to formation of the accumulation layer 136 in the semiconductor layer. Alternatively, a layer containing a negative charge, such as, for example, aluminum oxide, can be deposited over the second contact 132 (R. Hezel and K. Jaeger, J. Electrochem. Soc. 136, 518 (1989)).

An interruption of the n⁺-type layer, especially the inversion layer 94, 122, 134 in FIG. 7 to 9 in front of the second contact 82, 108, 132, can be attained beyond the metal region in accordance with the invention through oblique irradiation of the arrangement with energy-rich radiation, for example, hard UV light or the like. Here once again the effect of the self-shadowing of the elevations is used. The beaming angle must moreover be greater than the angle selected with oblique evaporation deposition of the contact metal.

According to a further proposal of the invention, the back of the solar cell, especially longitudinal flanks 138 of elevations upon which contact arrangements of the invention can be formed, have pyramid-like elevations 142 through treatment with an anisotropically acting texture etching which for their part are covered with a passivation layer 144. Through the chemical-mechanical polishing (CMP) previously mentioned by way of example, the longitudinal flanks 138 can be treated on their surfaces with the consequence that the pyramid-like projections 142 are removed on their tips so that flat areas 146 result which basically have a square shape in connection with the pyramid-like projections 142. A semiconductor substrate is exposed in these surfaces 146 so that as a consequence thereof the passivation layer 144 is interrupted. Subsequently the first and second contacts are formed.

As can be derived from the basic representation according to FIG. 10, the projections 142 are almost completely removed. There nonetheless remain trenches between the worn down projections 142 that are covered by the passivation layer 144. Through these measures it is possible to obtain a lining up of point contacts instead of a continuous linear contact which form the desired first and contacts, owing to which on the one hand, a smaller contact surface, and on the other a diminution of the negative influence due to the so-called “crowding effect” is attained to the extent that it is a matter of an MIS contact with the first contact collecting minority charge carriers. This means that the extent of the MIS contacts is greater in relation to their overall area, owing to which the minority charge carriers can flow without basic increase of the resistance into the contacts.

As was previously explained, the back structure can advantageously also be contoured such that the texturing, that is the generation of pyramids in particular, takes place only in the contact region on the longitudinal flanks, while a smooth semiconductor surface exists in the trench region. In this way, the enlargement of the surface due to the texture and the increase of charge carrier combination going along with it are avoided. A structure of this type can, as is made clear on the basis of FIG. 2, take place such that the longitudinal flanks are at least regionally constructed vertically or almost vertically in relation to the plane spanned by the semiconductor substrate and the trenches running between the flanks run under a desired angle toward the plane spanned by the semiconductor substrate, so that on the basis of the crystal orientation deviating from the (100) direction, a texturing is omitted.

The following can be generally noted on the contact arrangements formed in accordance with the invention:

In contrast to previous arrangements, the second contacts can possess spacings from one another of any desired smallness since an increased recombination on these contacts cannot occur as a consequence of screening. The maximum distance of the second majority charge carrier-collecting or ohmic contacts is given through the resistance of semiconductor foundation to the extent that the majority charge carriers (holes) coming from the front must cover an excessively far path to the contacts. In most cases of the arrangement of the invention, this case does not arise since the spacing of the second contacts is specified by the contact collecting the first minority carriers and this must be basically smaller than that normally existing between ohmic contacts on account of the restricted conductivity of the emitter layer (inversion layer of the n⁺-type layer). The spacings of the first contacts toward one another and therewith also of the second contacts toward one another move between 50 μm and 3 mm.

The width B of the elevations and therewith the spacings of first and second contacts in relation to one another can range according to the diffusion length of the minority charge carriers from 5 μm up to over 2 mm, but should be smaller than double the diffusion length of the minority charge carriers to the extent that an n⁺-type layer or an inversion layer runs along the semiconductor surface. The width of the contact fingers should preferably lie in the range from 1 μm and 100 μm. As a rule, the contact will only cover one part of the flank of the elevations which range in their respective height H between 20 μm and 150 μm.

The thickness D of the semiconductor substrate in the trench region (without elevations) should be basically smaller that the diffusion length of the minority charge carriers-as a rule between 30 μm and 300 μm. The respective thickness of the semiconductor substrate can be adjusted through the depth of the trenches and consequently be focused on the material in the solar cell process.

The back configuration of the invention is also suited for use of incident light on the back, since the shadowing by the contacts as a consequence of their arrangement on the steep flanks is very slight and the charge carriers are generated very near to the contacts. If a semiconductor material with very short diffusion lengths, such as, for example, polycrystalline silicon, is present, then a contact system for collecting minority charge carriers can be applied on the front side of the solar cell that is connected with the corresponding back contacts so that a bilateral collection of minority charge carriers takes place. Front and back sides can be provided with a trench structure for this purpose, whereby advantageously the front side trenches and therewith the elevations extending between them running perpendicular to the trenches and elevations and the former are provided only on respectively one trench flank with contacts collecting minority charge carriers.

The front side should (exclusively with exclusively back side collection arrangements, possess a very low surface recombination speed. Preferably this is assured through the application of a passivation layer which if need be at the same time serves as an anti-reflex layer. The so-called plasma silicon nitride generated in plasma with the aid of chemical vapor deposition, for example, through the reaction of SiH₄ and NH₃ is suited for this, with which the surface conditions of the semiconductors are saturated by hydrogen. CVD-SiO₂ and Al₂O₃ come into question.

Amorphous silicon manufactured in plasma and containing hydrogen (a-Si:H) is also suitable for passivation of the semiconductor surface on the front and back. This can be n-doped or p-doped, or be undoped. A multilayer should be used as the passivation layer system to avoid an inversion layer in the semiconductor material. Here a layer of amorphous Si, and on this, for example, an SiN, a plasma SiN or an SiO₂ layer, should run on the substrate side.

The series of a very thin intrinsically conducting a-Si:H layer on crystalline silicon, covered with a p-type or n-type doped a-Si:H layer has a very good passivating effect. The charge carriers can be guided to the contacts (contact fingers) through a TCO layer lying above it. The SiO₂ generated by the thermal reaction of oxygen and silicon can likewise serve as a good passivation layer, but requires very high temperatures around 1000° C.(400° C.-600° C. suffice with SiN). The necessary very low optical reflection is attained by an optimization of the passivation layer as an anti-reflex layer as well as through a suitable texture (pyramids and the like) of the surface. Advantageously a so-called floating junction (n⁺-type or p⁺-type layer) can also be generated on the front side and be covered with an anti-reflex of passivation layer.

With the solar cell of the invention, a system of intermeshing, preferably linear emitter and base contacts (fingers) are present on one side. With regard to the application of one or more collection bars for local contacting of all minority charge carrier contacts (emitters) as well as majority charge carrier contacts (base), it should be noted that following possible prior regional removal of the passivation layer from the first and second contacts (contact fingers), the respective collecting bar (busbar) is applied running vertically in relation to the metal fingers over the trenches and elevations in the form of a narrow metal band. The conductive connection of the collection bar (metal band) with the contact fingers takes place in accordance with the invention through a conductive adhesive applied previously to the solar cell or on the metal bands either continuously or point-wise, which is hardened at relatively low temperatures (perhaps up to max. 400° C.) (Conductive Adhesive Joining Technology). The metal bands serve as collection bars (busbars) as well as for connection of individual cells among one another. The connection of the collection bar with the contact fingers can also take place through a soldering process, however.

Flexible foils or plates can be used for the back structure of the invention in which collection bar pairs of different polarity run on one side of the solar cell to simplify contacting and connection of the cells on which the wiring structure is printed in the form of metallic conductor paths forming the respective collection and connection bars. The solar cells are fastened following local application of the conductive adhesive onto the solar cell or onto the conductor paths printed on these printed circuits. The adhesive mostly consists of metal particles situated in an epoxy matrix. This method of the invention means a basic simplification of the assemblage of the individual cells into modules and permits a problem-free automation of module manufacture.

In order that the respective collection bar (metal band) running perpendicular toward the contact fingers do not short circuit the first and second contacts (metal fingers) situated on two sides of the elevations at different potential, in order than only one grid structure is contacted, the respectively other grid structure must be interrupted at the site of the collection bar. This takes place in accordance with the invention by selective shadowing, preferably through a wire a small metal band arranged right in front of the semiconductor substrate, and indeed during the oblique evaporation deposition of the metal to form the first and second contacts. This is of particular advantage since the metal evaporation deposition takes place directed in a vacuum and consequently a sharply delimited interruption of the metal fingers takes place.

An advantageous application of the double contact arrangement for the front side exists for thin layer solar cells on a foreign substrate (R. Lüdemann et al., Proc. 26^{th} IEEE DVSC (1997), p. 159). In this case the semiconductor material can be applied directly on the conducting or non-conducting substrate under optimal conditions without having to take the presence of a backside metal between semiconductor and substrate into consideration. In order to be able to realize the arrangement of the invention for thin layer solar cells on the side facing the light, the trench structure illustrated in the figures is introduced into the substrate and the semiconductor layer is manufactured hereon if need be after application of an intermediate layer. It is therewith also possible for thin layer solar cells to use all advantages of the invention mentioned above, such as, for example, application of both contacts by oblique evaporation deposition in a vacuum, problem-free separation of emitter and base regions, in the case of silicon, use of economical aluminum as a contact material, minor shadowing through the contacting despite double contact structure, simple contacting of solar cells on one side, integral interconnection, etc.

With a thin layer solar cell, the structure (elevations) are moreover not constructed in the semiconductor substrate itself, since this is applied to a correspondingly structured carrier. Regardless of this, first and second contacts can then be applied and constructed on the substrate in the previously described manner due to the structure [of the] specified elevations so that the features disclosed to this extent correspondingly applies for front contact construction of thin layer solar cells without further explanations being necessary.

1. Solar cell (10) including a semiconductor substrate (16) with first and second contacts (26, 28; 58, 60; 80, 82; 106, 108; 132) for collecting and discharging minority and majority charge carriers generated by incident radiation energy in the semiconductor substrate, whereby at least the back surface of the semiconductor substrate has line or bar-like elevations (18, 50, 52, 54, 56, 78, 104, 130, 140) with respectively first and second longitudinal flanks (20, 22, 62, 74, 76, 110, 112) running parallel, whereby the first and second contacts are arranged on the back surface of the semiconductor substrate spaced from one another, wherein the first and second longitudinal flank (20, 22, 62, 64, 74, 76, 110, 112) of the elevation (18, 50, 52, 54, 56, 78, 104, 130, 140) pass over into one another through an outer segment (24, 72, 86, 114) running parallel or approximately parallel to the plane spanned by the semiconductor substrate (16), wherein on at least some of the elevations, the first contacts (26, 58, 80, 106) extend on the first longitudinal flanks (22, 62, 74, 110) of the elevations and the second contacts (28, 60, 82, 108) on the second longitudinal flanks (20, 64, 76, 112) of the elevations, and wherein the first and second contacts are spaced from one another on the trench side as well as on the exterior segment side.

2. Solar cell according to claim 1, wherein the elevations (18, 50, 52, 54, 56, 78, 104, 130, 140) have a U, V or sawtooth shape in section, wherein the trench bottom runs at least segment-wise parallel or approximately parallel to the plane spanned by the semiconductor substrate (16) and wherein the first or second contact (26, 58, 80, 106; 28, 60, 82, 108) preferably extend up to the outer rim (102, 104) of the first or second longitudinal flank (20, 22, 62, 64, 74, 76, 110, 112) of the elevation as well as up to the trench bottom, or spaced from the latter.

3. Solar cell according to claim I or 2, wherein the semiconductor substrate (16) is highly doped by, for example, diffusion, ion implantation or alloying and/or is inverted and/or has a hetero-transition at least in its surface running under the first and/or the second contact (26, 28; 58, 60; 80, 82; 106, 108; 132).

4. Solar cell according to at least claim 1, wherein the contact (58, 80, 106) collecting the minority charge carriers is a metal/semiconductor and/or a MIS (metal insulator semiconductor) contact.

5. Solar cell according to at least claim 1, wherein the second contact collecting the majority charge carriers is a metal contact (28) applied directly on the semiconductor substrate (16) and/or a metal contact (60, 82, 108) applied to a highly doped semiconductor substrate.

6. Solar cell according to at least one of the preceding claims, wherein at least a first passivation layer (66, 96, 114) extends along the back surface of the semiconductor substrate (16).

7. Solar cell according to at least one of the preceding claims, wherein the back surface of the semiconductor substrate (16) has a minority charge carrier on the minority charge carrier layer (emitter layer) (94, 122) conducting these collecting first contacts (58, 80, 106) that is separated with regard to potential from the contacts (60, 82, 108) conducting the (second) contacts collecting majority charge carriers.

8. Solar cell according to at least one of the preceding claims, wherein the emitter layer (94, 122) is formed in the surface region of the semiconductor substrate and/or is influenced by charges in the first passivation layer (96, 114) applied directly on the semiconductor structure.

9. Solar cell according to at least one of the preceding claims, wherein the semiconductor substrate (16) is a p-type doped semiconductor and the emitter layer (94, 122) is a highly doped n-type layer (n⁺) and/or an n-type conducting inversion layer or a hetero-transition formed by positive charges in the first passivation layer (96, 114).

10. Solar cell according to at least one of the preceding claims, wherein the first and/or second contact (80, 82) are arranged regionally on the segment of the first or second longitudinal flank (74, 76), directly on the latter or on an insulator layer (88), previously covered with passivation material and then exposed from it.

11. Solar cell according to at least one of the preceding claims, wherein the first and/or second contacts (26, 28; 58, 60; 80, 82; 106, 108; 132) run linearly in the longitudinal direction for the first or second longitudinal flanks (20, 22, 62, 64, 74, 76, 110, 112) and on these.

12. Solar cell according to at least one of the preceding claims, wherein the first and/or second contact (26, 28; 58, 60; 80, 82; 106, 108; 132) preferably run in the upper longitudinal rim side half of the first or second longitudinal flank (20, 22, 62, 64, 74, 76, 110, 112).

13. Solar cell according to at least one of the preceding claims, wherein at least the first or second longitudinal flank (138) having the first and/or the second contact has a texture (144).

14. Solar cell according to at least one of the preceding claims, wherein the texture is formed by pyramid-like projections (144).

15. Solar cell according to at least one of the preceding claims, wherein the linear or strip-like elevation (78, 104, 130, 140) having the first and second longitudinal flank (74, 76, 110, 112) has a breadth B in its semiconductor substrate side base (55) which is smaller or equals double the diffusion length of the minority charge carrier in the semiconductor substrate (16).

16. Solar cell according to at least one of the preceding claims, wherein the first and second contacts (80, 82; 106, 108; 132) proceeding from an elevation (78, 104, 130, 140) with its respective elevation base side longitudinal edges span a first plane, and wherein a sectional plane (57) intersecting with the longitudinal flanks (62, 64) running parallel to the plane spanned by the semiconductor substrate has a breadth B that is smaller than or equal to double the diffusion length of the minority charge carrier in the semiconductor substrate between the first plane and the semiconductor layer side base (55) of the elevation.

17. Solar cell according to at least one of the preceding claims, wherein the spacing between the base center of the elevation (78, 104, 130, 140) on the rim running on the base side of the second contact (82, 108) is greater than half the breadth of the basis (55).

18. Solar cell according to at least one of the preceding claims, wherein the breadth B of the base (55) of the elevation (56) or the sectional plane (57) comes to 5 μm≦B≦2 mm.

19. Solar cell according to at least one of the preceding claims, wherein the semiconductor substrate (16) has a thickness D with 20 μm≦D≦300 μm outside the elevation.

20. Solar cell according to at least one of the preceding claims, wherein the solar cell (10) is structured on the front side by parallel-running trenches that for their part run perpendicular to the elevations (18, 50, 52, 54, 56, 78, 104, 130, 140) on the back (14) of the solar cell.

21. Solar cell according to at least one of the preceding claims, wherein the front surface of the solar cell (10) has a passivation layer and/or anti-reflection layer.

22. Solar cell according to at least one of the preceding claims, wherein the passivation layer is the antireflection layer.

23. Solar cell according to at least one of the preceding claims, wherein the passivation layer (172) or the anti-reflection layer consists of plasma silicon nitride.

24. Solar cell according to at least one of the preceding claims, wherein the first and/or second contacts (26, 28, 58, 60, 80, 82, 106, 108, 132) running parallel to one another are connected through a collection contact such as a metal band respectively running perpendicular or basically perpendicular to this.

25. Solar cell according to at least one of the preceding claims, wherein the collector contact is connected with the respective first or second contacts, especially through a conductive adhesive.

26. Solar cell according to at least one of the preceding claims, wherein the semiconductor material is monocrystalline, polycrystalline or amorphous or is an element or semiconductor material.

27. Solar cell according to at least one of the preceding claims, wherein the passivation layer consists of or contains SiO₂, SiN, Al₂O₃, a-Si, a-Si:H.

28. Solar cell according to at least one of the preceding claims, wherein the passivation layer consists of a double or multiple layer with a-Si or a-Si:H running on the substrate side over which at least one layer, preferably of SiN, SiO₂, is arranged.

29. Solar cell according to at least one of the preceding claims, wherein the emitter layer (94, 122) runs spaced in relation to the second contact (82, 108).

30. Solar cell according to at least one of the preceding claims, wherein the passivation layer indirectly or directly prevents a charge carrier transport between first and second contact or basically prevents it.

31. Solar cell in the form of a thin layer solar cell in which the first and second minority or majority charge carrier-collecting contacts are arranged on the front surface of the semiconductor substrate constructed and/or arranged according to at least one of the preceding claims.

32. Method for manufacturing a solar cell according to at least one of the preceding claims, including a semiconductor substrate with front and back side in which minority and majority charge carriers are generated through incident radiation energy, which are collected and discharged by first and second contacts running over back surfaces having elevations delimiting first trenches having strip or bar-like first and second longitudinal flanks, whereby the first and/or second electrical contacts are applied directly on the back surface or are applied following whole are or largely whole area covering of the back surface with a passivation layer and if need be removal of regions of the passivation layer and on regions of the semiconductor substrate thus exposed, wherein the first trenches of the back are constructed with trench bottoms and elevations of the back with outer segments which run parallel to the plane spanned by the semiconductor substrate, wherein on at least some of the elevations, the first electrical contacts are applied on the first longitudinal flanks of the elevations and the second electrical contacts on the second longitudinal flanks of the elevations such that the first and second electrical contacts are spaced from one another on the trench bottom side as well as on the outer segment side.

33. Method according to claim 32, wherein the first and/or second contact is applied by evaporation deposition of material under an angle α a in relation to the normal proceeding from the plane spanned by the semiconductor substrate, whereby the angle of evaporation deposition α comes to α≠0° and α≠90°.

34. Method according to claim 32 or 33, wherein ions are implanted free of masking for doping the first and/or second longitudinal flank, especially beneath the first and/or second contact to be constructed on this such that these arise under an angle of incidence β toward the normal, whereby the angle of incidence β comes to β≠0°, β≠90°.

35. Method according to at least one of claims 32 to 34, wherein a highly doper layer is formed in the semiconductor substrate in particular by local heating by, for example, laser irradiation and/or light irradiation of the first and/or second longitudinal flange, whereby in particular areal extension of the highly doped layer is equal or greater than the areal extension of the first and/or second contact on the semiconductor substrate, whereby the first and/or second flank are irradiated especially when using shadowing brought about by the elevations.

36. Method according to at least one of claims 32 to 35, wherein the first contacts are constructed in a first oblique evaporation deposition step and then the second contacts are constructed in a second evaporation deposition step or the reverse.

37. Method according to at least one of claims 32 to 36, wherein the back surface of the semiconductor substrate is covered over the whole surface or basically over the entire surface with a passivation layer and then, preferably through chemical-mechanical polishing, at least the passivation material and if need be semiconductor material are worn away in the free longitudinal rim region of the elevations as well as especially [in] the plateau-like region running between the longitudinal regions to form the outer segment.

38. Method according to at least one of claims 32 to 37, wherein the first and/or second contact if need be runs regionally on the elevation side of the passivation layer.

39. Method according to at least one of claims 32 to 38, wherein the back surface of the semiconductor substrate is covered with a further passivation layer or a passivation layer system preventing a short circuit after if need be necessary electrical separation of the first and second contacts proceeding from a common elevation.

40. Method according to at least one of claims 32 to 39, wherein tunnel oxide layers for the first contacts to be constructed as MIS contacts are formed during tempering by oxygen administration in the region of the first longitudinal flanks of the elevations.

41. Method according to at least one of claims 32 to 40, wherein regional removal of the first passivation layer or of the metal present [in] segments of elevations extending along the first and second longitudinal flanks [takes place] in particular through chemical-mechanical polishing such that the elevations are oriented in the direction of motion of a polishing element with a translatory or rotary motion such that these run parallel to each other or under an angle β with 1° C.≦β≠30° C.

42. Method according to at least one of claims 32 to 41, wherein a local back field is formed, for example by boron implantation, boron diffusion or alloying with aluminum, for example preferably prior to applying the metal to construct the second contact in the region of the latter.

43. Method according to at least one of claims 32 to 42, wherein a layer (emitter layer) discharging minority charge carriers is formed under the first passivation layer, preferably by diffusion by doping atoms such as phosphorus.

44. Method according to at least one of claims 32 to 43, wherein the emitter layer is formed by increasing the positive charge density, especially by incorporating alkaline metal-containing substances in the first passivation layer, such as a silicon nitride layer, whereby the increase of the charge density preferably lies at a distance d with 1 nm<d<10 nm from the semiconductor surface.

45. Method according to at least one of claims 32 to 44, wherein regions of longitudinal flanks are shadowed perpendicular or almost perpendicular to their longitudinal extension prior to constructing the first and/or second contacts, and an additional contact electrically conductively connecting the first or second electrical contacts is applied on such a shadowed region.
